(19) United States
(12) Patent Application Publication
(10) Pub. No.: US 2011/0302540 A1
(43) Pub. Date: Dec. 8, 2011

(54) SEMICONDUCTOR DEVICE COMPRISING SHIELD TREE AND RELATED LAYOUT METHOD

(75) Inventors: Seok-Il KWON, Seoul (KR); Hoi Jin LEE, Seoul (KR)

(73) Assignee: SAMSUNG ELECTRONICS CO., LTD., Suwon-si (KR)

(21) Appl. No.: 13/041,804

(22) Filed: Mar. 7, 2011

(30) Foreign Application Priority Data
Jun. 8, 2010 (KR) 10-2010-0054024

(51) Int. Cl. G06F 17/50; G01R 31/26; H05K 9/00

(52) U.S. Cl. 716/100; 361/816; 324/762.01

(57) ABSTRACT

A semiconductor device comprises a plurality of flip-flops, a clock tree for transferring an externally input clock signal to the flip-flops, and a shield tree configured to shield the clock tree. The shield tree transmits a control signal to activate the flip-flops in a test operation mode of the semiconductor device.

### CROSS-REFERENCE TO RELATED APPLICATIONS

This application claims priority under 35 U.S.C. §119 to Korean Patent Application No. 10-2010-0054024 filed on Jun. 8, 2010, the disclosure of which is hereby incorporated by reference in its entirety.

### BACKGROUND OF THE INVENTION

Embodiments of the inventive concept relate generally to semiconductor devices. More particularly, embodiments of the inventive concept relate to semiconductor devices comprising a shield tree and a method of laying out the shield tree.

A semiconductor device typically comprises signal lines for transmitting control signals and data to different functional blocks. The timing of the control signals can be controlled according to an internally generated clock signal or in synchronization with an externally provided clock signal.

The externally provided clock signal can be transmitted to target elements through a clock tree in the semiconductor device. The clock tree is typically designed to prevent the clock signal from being distorted during transmission. Accordingly, the clock tree is commonly made of a metal line or layer providing low signal attenuation capable of being readily formed during semiconductor fabrication.

To prevent the clock tree from receiving interference from peripheral control signal lines or data lines, the semiconductor device can include a shield tree for the clock tree. The shield tree typically comprises a metal line formed adjacent to the clock tree.

As the integration density and complexity of semiconductor devices continues to increase, it becomes increasingly difficult to form a shield tree capable of shielding the clock line from interference from adjacent signal lines. This difficulty can arise because the shield tree is required to cover a relatively large area within a limited amount of space.

### SUMMARY OF THE INVENTION

Embodiments of the inventive concept provide a semiconductor device comprising a shield tree and a method of laying out the shield tree.

According to one embodiment of the inventive concept, a semiconductor device comprises a plurality of flip-flops, a clock tree for transferring an externally generated input clock signal to the plurality of flip-flops, and a shield tree formed to provide shielding to the clock tree. The shield tree transmits a control signal to activate the flip-flops in a test operation mode of the semiconductor device.

In certain embodiments, the clock tree comprises a plurality of metal clock lines formed in a plurality of metal layers and connected to each other through corresponding vias.

In certain embodiments, the shield tree comprises a first shield tree that transmits the control signal and a second shield tree electrically isolated from the first shield tree.

In certain embodiments, the first shield tree comprises a plurality of metal shield lines formed in a plurality of metal layers and connected to each other through corresponding vias.

In certain embodiments, the second shield tree is connected to a power supply voltage or ground.

In certain embodiments, the semiconductor device further comprises a plurality of clock buffers connected to the clock tree to control fan-out and skew of the clock signal.

In certain embodiments, the semiconductor device further comprises a plurality of control signal buffers formed in the shield tree adjacent to the clock buffers and configured to transmit the control signal.

In certain embodiments, each of the clock buffers and control signal buffers comprises an inverter circuit.

In certain embodiments, the control signal buffers provide shielding to a via through which the clock buffers are connected to the clock tree.

In certain embodiments, the semiconductor device further comprises a clock signal input port that receives the clock signal from an external source and transmits the clock signal to the clock tree, and a control signal input port that receives the control signal from an external source and transmits the control signal to the shield tree.

In certain embodiments, the control signal is deactivated during a normal operation mode of the semiconductor device.

In certain embodiments, the clock signal input port transmits the clock signal to the clock tree after a lapse of specific delay time from a transition point of the control signal in the test operation mode of the semiconductor device.

According to another embodiment of the inventive concept, a computer-implemented method of determining a layout for a semiconductor device comprising a plurality of flip-flops is provided. The method comprises determining a layout of a clock tree for transmitting a clock signal to the respective flip-flops, and determining a layout of a shield tree for shielding the clock tree. The shield tree is configured to transmit a control signal for activating a test operation mode of the flip-flops, and the shield tree is configured to be connected to an input port of the control signal.

In certain embodiments, the shield tree comprises a first shield tree configured to transmit the control signal and a second shield tree electrically isolated from the first shield tree.

In certain embodiments, the second shield tree is configured to be connected to a power supply voltage or ground.

In certain embodiments, determining the layout of the clock tree comprises allocating a plurality of clock buffers to the clock tree to control fan-out and delay of the clock signal.

In certain embodiments, determining the layout of the shield tree comprises allocating a plurality of control signal buffers to the shield tree to transmit the control signal, and the control signal buffers are formed adjacent to the clock buffers.

According to still another embodiment of the inventive concept, a method is provided for performing a test operation in a semiconductor device comprising a plurality of flip-flops, a clock tree for transferring an externally generated input clock signal to the plurality of flip-flops, and a shield tree formed to provide shielding to the clock tree. The method comprises transmitting a control signal through the shield tree to activate the flip-flops in a test operation mode of the semiconductor device.

In certain embodiments, the method further comprises deactivating the control signal during a normal operation mode of the semiconductor device.

In certain embodiments, the semiconductor device comprises a flash memory device.

### BRIEF DESCRIPTION OF THE DRAWINGS

The drawings illustrate selected embodiments of the inventive concept. In the drawings, like reference numbers indicate like features.

FIG. 1 is a block diagram of a semiconductor device comprising a shield tree according to an embodiment of the inventive concept.

FIGS. 2A, 2B, and 2C are timing diagrams illustrating a clock signal and a scan enable signal according to an embodiment of the inventive concept.

FIG. 3 is a block diagram of a semiconductor device comprising a shield tree according to another embodiment of the inventive concept.

FIGS. 4A, 4B, and 4C are timing diagrams illustrating voltage levels of a clock signal, a scan enable signal, and a shield tree according to an embodiment of the inventive concept.

FIG. 5 is a block diagram of a semiconductor device comprising a shield tree according to yet another embodiment of the inventive concept.

FIG. 6 is a cross-sectional view illustrating a detailed configuration of a region shown in FIG. 5.

FIG. 7 is a flowchart illustrating a method of determining a layout for a shield tree and a clock tree according to an embodiment of the inventive concept.

### DETAILED DESCRIPTION

Embodiments of the inventive concept are described below with reference to the accompanying drawings. These embodiments are presented as teaching examples and should not be construed to limit the scope of the inventive concept.

In general, embodiments of the inventive concept relate to semiconductor memory devices comprising a shield tree. For explanation purposes, some of the described embodiments comprise a shield tree that prevents interference from a scan enable signal SE. However, the shield tree can be used in conjunction with other types of control signals. In general, a control signal can be any signal that can be activated (e.g., switched to logic ‘high’) or deactivated (e.g., switched to logic ‘low’) in various operation modes. In certain embodiments described below, scan enable signal SE is activated only in a test operation mode.

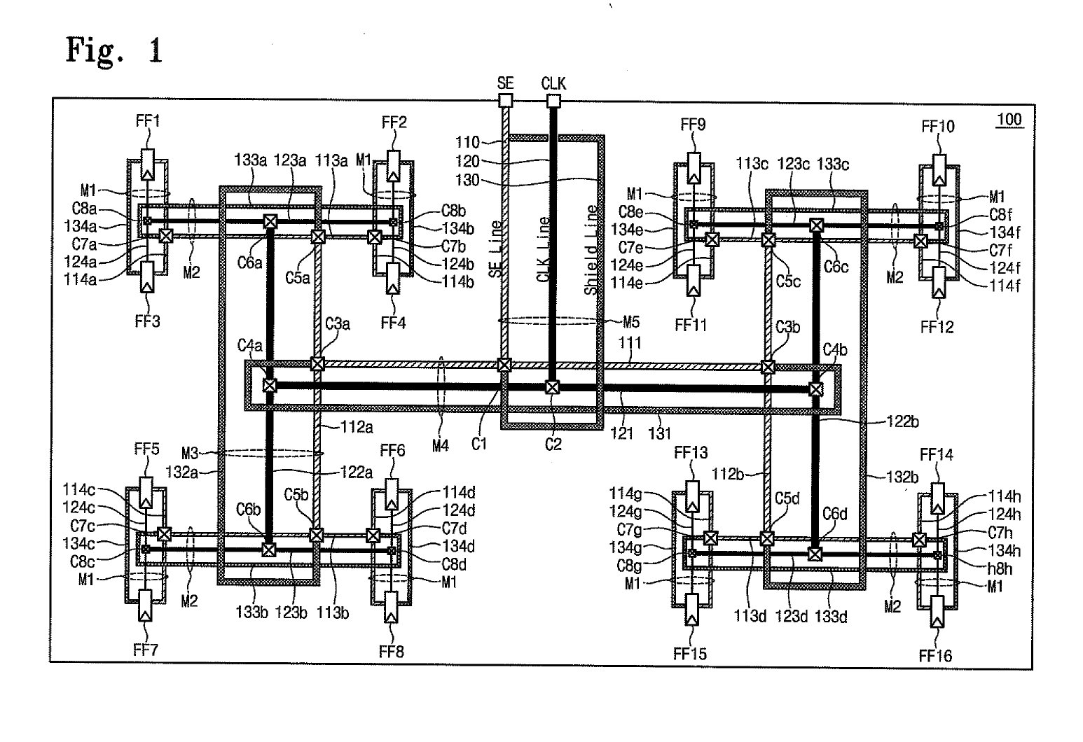

FIG. 1 is a block diagram of a semiconductor device 100 comprising a shield tree according to an embodiment of the inventive concept.

Referring to FIG. 1, semiconductor device 100 comprises a plurality of flip-flops FF1˜FF16 each receiving a clock signal CLK and a scan enable signal SE. Semiconductor device 100 further comprises clock lines 120, 121, 122a, 122b, 123a, 123b, 123c, 123d, 124a, 124b, 124c, 124d, 124e, 124f, 124g, and 124h forming a clock tree for transmitting clock signal CLK to flip-flops FF1˜FF16.

Semiconductor device 100 further comprises shield lines 110, 111, 112a, 112b, 113a, 113b, 113c, 113d, 114a, 114b, 114c, 114d, 114e, 114f, 114g, and 114h forming a shield tree for transmitting scan enable signal SE to flip-flops FF1˜FF16. Shield lines that transmit scan enable signal SE can alternatively be referred to as scan control lines.

Semiconductor device 100 further comprises shield lines 130, 131, 132a, 132b, 133a, 133b, 133c, 133d, 134a, 134b, 134c, 134d, 134e, 134f, 134g, and 134h for providing shielding to the clock tree.

Flip-flops FF1˜FF16 are circuits that store input data for semiconductor device 100 or internally processed data. Each of flip-flops FF1˜FF16 latches or outputs data in synchronization with clock signal CLK transmitted through the clock tree.

In a test mode, flip-flops FF1˜FF16 store and output test data in response to scan enable signal SE. Scan enable signal SE is deactivated (e.g., switched to logic ‘low’) in a normal operation mode.

Shield lines 110, 111, 112a, 112b, 113a, 113b, 113c, 113d, 114a, 114b, 114c, 114d, 114e, 114f, 114g, and 114h transmit scan enable signal SE to flip-flops FF1˜FF16. Although shield lines 110, 111, 112a, 112b, 113a, 113b, 113c, 113d, 114a, 114b, 114c, 114d, 114e, 114f, 114g, and 114h are electrically connected to one another, they can be formed by different metal layers. Shield line 110, which is formed at an uppermost metal layer (e.g., M5), is electrically connected to an SE port to which scan enable signal SE is input from an external source.

In some embodiments, a base of the shield tree is not connected to the uppermost metal layer (e.g., M5). In such embodiments, the SE port is electrically connected to another metal layer connected to the base of the shield tree.

Shield line 110 is electrically connected to shield line 111 formed at another metal layer (e.g., M4) through a contact structure such as a via C1. Shield line 113a is electrically connected to shield lines 114a and 114b formed at another metal layer (e.g., M1) through vias C7a and C7b. Shield lines 114a and 114b are electrically connected to an input terminal of scan enable signal SE of flip-flops FF1, FF2, FF3, and FF4 by way of a contact structure such as another via.

Shield lines 110, 111, 112a, 112b, 113a, 113b, 113c, 113d, 114a, 114b, 114c, 114d, 114e, 114f, 114g, and 114h are electrically connected to respective shield lines 130, 131, 132a, 132b, 133a, 133b, 133c, 133d, 134a, 134b, 134c, 134d, 134e, 134f, 134g, and 134h for providing shielding to the clock line. Alternatively, shield lines 110, 111, 112a, 112b, 113a, 113b, 113c, 113d, 114a, 114b, 114c, 114d, 114e, 114f, 114g, and 114h can be configured to connect the shield tree to the SE port. In this case, shield lines of respective metal layers can be electrically connected through a via to form a shield tree for transmitting scan enable signal SE to flip-flops FF1˜FF16.

Although only the shield tree transferred to flip-flops FF1, FF2, FF3, and FF4 has been described herein, the shield tree can be formed similarly with respect to other flip-flops FF5˜FF16. Therefore, the shield tree for flip-flops FF5˜FF16 will not be described in further detail.

Clock lines 120, 121, 122a, 122b, 123a, 123b, 123c, 123d, 124a, 124b, 124c, 124d, 124e, 124f, 124g, 124h transmit clock signal CLK to flip-flops FF1˜FF16. For brevity of description, only paths along which a clock signal is transferred to flip-flops FF1˜FF4 will be described hereinafter. However, a clock signal can be transmitted to other flip-flops FF5˜FF16 in a similar manner to flip-flops FF1˜FF4.

Clock line 120 is formed at a metal layer (e.g., M5) disposed at an uppermost one of the metal layers. Clock line 120 is electrically connected to a CLK port to which clock signal CLK is input from an external source. Clock line 120 is electrically connected to clock line 121 formed at another metal layer (e.g., M4) through a via C2. Clock line 120 and shield line 110 are electrically isolated from each other.

Clock line 121 is electrically connected to clock lines 122a and 122b formed at another metal layer (e.g., M3) through vias C4a and C4b. Clock line 122a is electrically connected to clock lines 123a and 123b formed at another metal layer (e.g., M2) through vias C6a and C6b. Clock line 123a is electrically connected to clock lines 124a and 124b formed at another metal layer (e.g., M1) through vias C8a and C8b. Although not shown in the drawings, clock lines 124a and 124b can be electrically connected to an input terminal of clock signal CLK of flip-flops FF1, FF2, FF3, and FF4 by way of a contact structure such as a via.

Shield lines 130, 131, 132a, 132b, 133a, 133b, 133c, 133d, 134a, 134b, 134c, 134d, 134e, 134f, 134g, and 134h are electrically connected to respective shield lines 110, 111, 112a, 112b, 113a, 113b, 113c, 113d, 114a, 114b, 114c, 114d, 114e, 114f, 114g, and 114h. For example, shield line 130 formed at an uppermost metal layer (e.g., M5) is electrically connected to shield line 150 formed at the same metal layer M5. Shield line 131 formed at metal layer M4 is electrically connected to shield line 111. Shield lines 132a and 132b formed at the metal layer M3 are electrically connected to respective shield lines 112a and 112b. Shield lines 133a, 133b, 133c, and 133d formed at metal layer M2 are electrically connected to respective shield lines 113a, 113b, 113c, and 113d. Shield lines 134a, 134b, 134c, 134d, 134e, 134f, 134g, and 134h formed at metal layer M1 are electrically connected to respective shield lines 114a, 114b, 114c, 114d, 114e, 114f, 114g, and 114h.

Shield lines 130, 131, 132a, 132b, 133a, 133b, 133c, 133d, 134a, 134b, 134c, 134d, 134e, 134f, 134g, and 134h are electrically connected to corresponding shield lines 110, 111, 112a, 112b, 113a, 113b, 113c, 113d, 114a, 114b, 114c, 114d, 114e, 114f, 114g, and 114h to have the same voltage level as scan enable signal SE. Accordingly, each of shield lines 130, 131, 132a, 132b, 133a, 133b, 133c, 133d, 134a, 134b, 134c, 134d, 134e, 134f, 134g, and 134h is set to logic ‘low’ in a normal operation mode. Thus, shield lines may provide shielding for a clock tree in a normal operation mode. Meanwhile, each of shield lines 130, 131, 132a, 132b, 133a, 133b, 133c, 133d, 134a, 134b, 134c, 134d, 134e, 134f, 134g, and 134h transitions to logic ‘high’ in a test operation mode.

In semiconductor device 100, a shield tree for providing scan enable signal SE in a test operation mode is shared with shield lines for providing shielding to a clock tree. Accordingly, semiconductor device 100 need not form an additional signal tree for providing scan enable signal SE. As a result, the design complexity of metal layers can be reduced, and a limited amount of metal can be used efficiently.

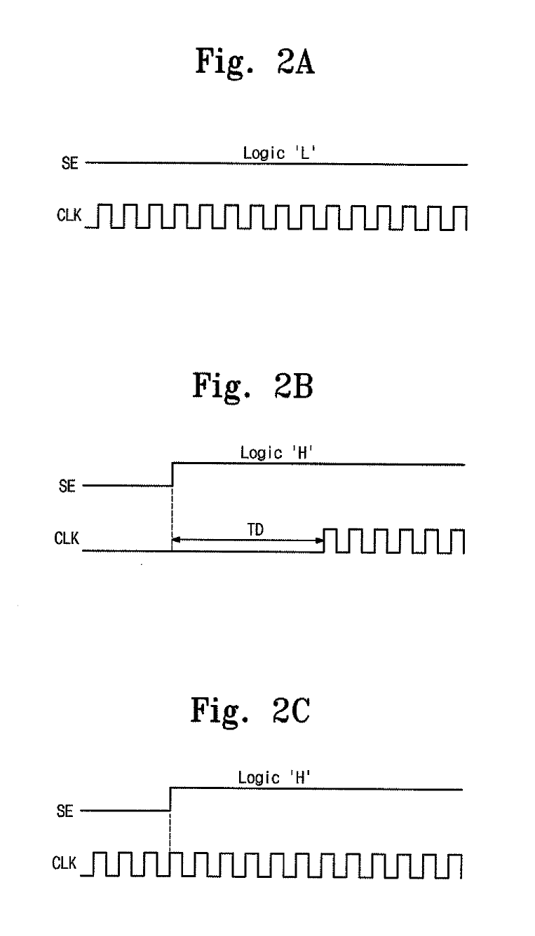

FIGS. 2A, 2B, and 2C are waveform diagrams illustrating the operation of scan enable signal SE and clock signal CLK of FIG. 1. FIG. 2A shows waveforms of signals SE and CLK in a normal operation mode, and FIGS. 2B and 2C show waveforms of signals SE and CLK in a test operation mode.

Referring to FIG. 2A, scan enable signal SE is maintained in an inactive state (e.g., logic ‘low’) in the normal operation mode. Thus, shield lines 110, 111, 112a, 112b, 113a, 113b, 113c, 113d, 114a, 114b, 114c, 114d, 114e, 114f, 114g, and 114h electrically connected to the SE port are maintained at logic ‘low’ (e.g., ground VSS). Shield lines 130, 131, 132a, 132b, 133a, 133b, 133c, 133d, 134a, 134b, 134c, 134d, 134e, 134f, 134g, and 134h are also maintained at logic ‘low’ in the normal operation mode. Thus, shield lines provide shielding for clock line 120 in the normal operation mode.

In FIG. 2B, waveforms of scan enable signal SE and clock signal CLK in the test operation mode are shown. To enter the test operation mode, scan enable signal SE is first activated (e.g., switched to logic ‘high’). Thereafter, clock signal CLK is input to the clock CLK port after a lapse of a specific delay time TD and transferred to flip-flops FF1˜FF16. In the test mode operation, there is the specific delay time TD between a point where scan enable signal SE is activated and a point where clock signal CLK is input. Thus, a clock tree receives a shield from shield lines constituting a shield tree and shield lines electrically connected to a shield tree.

In FIG. 2C, waveforms of scan enable signal SE and clock signal CLK in another test operation mode are shown. Scan enable signal SE is activated while clock signal CLK is supplied. At a point where scan enable signal SE is deactivated (e.g., switched to logic ‘low’), shield lines, including both shield lines constituting a shield tree and shield lines not constituting a shield tree, provide shielding to a clock tree. And at a point where scan enable signal SE is activated (e.g., switched to logic ‘high’), the shield lines, including both shield lines constituting a shield tree and shield lines not constituting a shield tree, provide shielding to a clock tree.

At a point where scan enable signal SE transitions from logic ‘low’ to logic ‘high’, interference such as coupling effect may be transferred to a clock line. However, the interference may occur for a very short time. Therefore, shield lines, including both shield lines constituting a shield tree and shield lines not constituting a shield tree, of semiconductor device 100 may provide effective shielding for a clock tree.

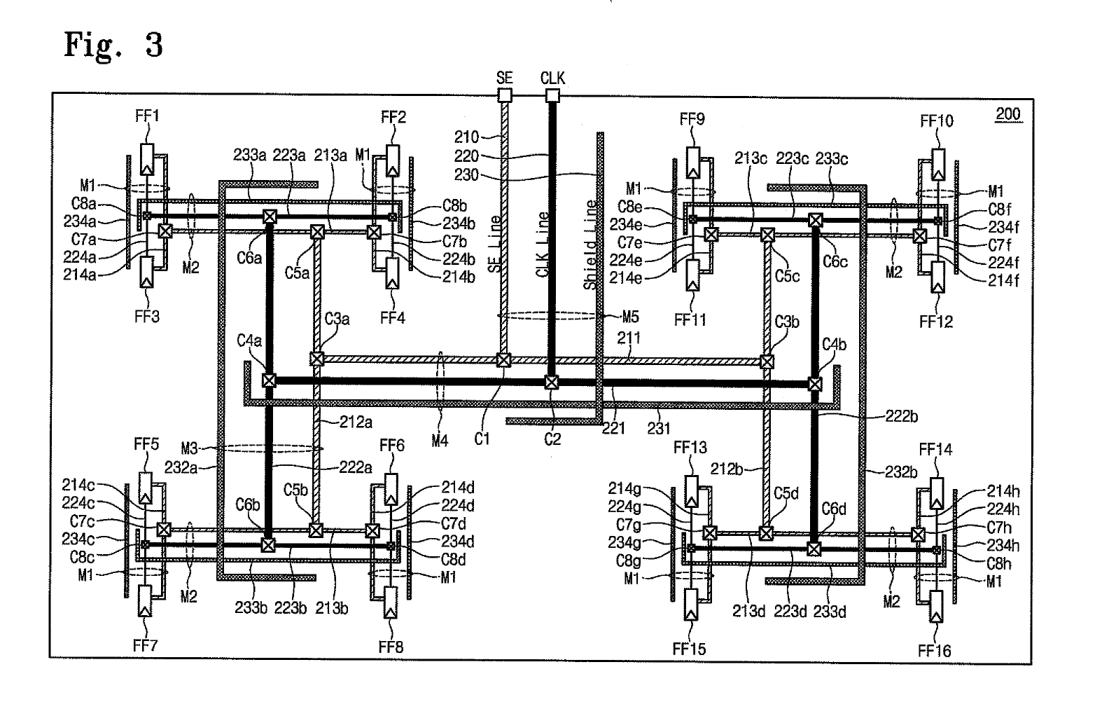

FIG. 3 is a block diagram of a semiconductor device 200 comprising a shield tree according to another embodiment of the inventive concept.

Referring to FIG. 3, semiconductor device 200 comprises a plurality of flip-flops FF1˜FF16 each receiving a clock signal CLK and a scan enable signal SE. Semiconductor device 200 comprises clock lines 220, 221, 222a, 222b, 223a, 223b, 223c, 223d, 224a, 224b, 224c, 224d, 224e, 224f, 224g, and 224h constituting a clock tree for transferring clock signal CLK to flip-flops FF1˜FF16. Semiconductor device 200 comprises shield lines 210, 211, 212a, 212b, 213a, 213b, 213c, 213d, 214a, 214b, 214c, 214d, 214e, 214f, 214g, and 214h constituting a shield tree for transferring scan enable signal SE to flip-flops FF1˜FF16.

Semiconductor device 200 further comprises shield lines 230, 231, 232a, 232b, 233a, 233b, 233c, 233d, 234a, 234b, 234c, 234d, 234e, 234f, 234g, and 234h for shielding a clock tree. Shield lines 210, 211, 212a, 212b, 213a, 213b, 213c, 213d, 214a, 214b, 214c, 214d, 214e, 214f, 214g, and 214h constituting a shield tree and shield lines 230, 231, 232a, 232b, 233a, 233b, 233c, 233d, 234a, 234b, 234c, 234d, 234e, 234f, 234g, and 234h not constituting a shield tree are electrically isolated from one another.

Flip-flops FF1˜FF16 are circuits storing data input to semiconductor device 200 or internally processed data. Each of the flip-flops latches or outputs data in synchronization with clock signal CLK transferred through a clock tree. In particular, in a test operation mode, flip-flops FF1˜FF16 store and output test data in response to scan enable signal SE. Thus, scan enable signal SE is deactivated (e.g., switched to logic ‘low’) in a normal operation mode.

Shield lines 210, 211, 212a, 212b, 213a, 213b, 213c, 213d, 214a, 214b, 214c, 214d, 214e, 214f, 214g, and 214h constitute a shield tree for transferring control signal SE to flip-flops FF1˜FF16. Shield line 210 can be formed at an uppermost metal layer (e.g., M5). Shield line 210 is electrically connected to an SE port for externally receiving a scan enable signal SE. Shield line 210 is electrically connected to shield line 211 formed at another metal layer M4 through a contact structure such as a via C1.

Shield line 211 is electrically connected to shield lines 212a and 212b formed at another metal layer M3 through vias C3a and C3b. Shield line 212a is electrically connected to shield lines 213a and 213b formed at another metal layer M2 through vias C5a and C5b. Shield line 213a is electrically connected to shield lines 214a and 214b formed at another metal layer M1 through vias C7a and C7b. Although not shown in the figures, shield lines 214a and 214b may be electrically connected to an input terminal of a scan enable signal SE of each of flip-flops FF1, FF2, FF3, and FF4 through a contact structure through anther via.

Shield lines 210, 211, 212a, 212b, 213a, 213b, 213c, 213d, 214a, 214b, 214c, 214d, 214e, 214f, 214g, and 214h constituting the shield tree provide shielding for a clock tree while transferring scan enable signal SE. That is, in a normal operation mode, as scan enable signal SE is fixed to a logic ‘low’, shield lines constituting a shield tree block electromagnetic interference transferred to the clock tree. In a test operation mode, as scan enable signal SE transitions to logic ‘high’, electromagnetic interference transferred to a clock tree may be blocked.

Connections among shield lines 210, 211, 212a, 213a, 214a, and 214b transferring scan enable signal SE to flip-flops FF1, FF2, FF3, and FF4 have been described herein. However, connections between shield lines with respect to the other flip-flips FF5˜FF16 can be similarly applied to shield lines 210, 211, 212a, 213a, 214a, and 214b. Therefore, connections between shield lines constituting a shield tree for flip-flops FF5˜FF6 will not be described herein.

Clock lines 220, 221, 222a, 222b, 223a, 223b, 223c, 223d, 224a, 224b, 224c, 224d, 224e, 224f, 224g, and 224h constituting the clock tree transfer clock signal CLK to flip-flops FF1˜FF16. The constitution of the clock tree formed by clock lines is similar to the example described with reference to FIG. 1. For brevity of description, only paths along which a clock signal is transmitted to flip-flops FF1˜FF4 will be described herein. However, clock signal CLK can be transmitted to other flip-flops FF5˜FF16 in a manner similar to flip-flops FF1˜FF4.

Clock line 220 is formed at an uppermost metal layer (e.g., M5). Clock line 220 is electrically connected to a CLK port to which clock signal CLK is externally input. Clock line 220 is electrically connected to clock line 221 formed at another meal layer M4 through a via C2. Clock line 220 and shield line 210 are electrically isolated from each other.

Clock line 221 is electrically connected to clock lines 222a and 222b formed at another metal layer M3 through vias C4a and C4b. Clock line 222a is electrically connected to clock lines 223a and 223b formed at another metal layer M2 through vias C6a and C6b. Clock line 223a is electrically connected to clock lines 224a and 224b formed at another metal layer M1 through vias C8a and C8b. Although not shown in the figures, clock lines 224a and 224b may be electrically connected to an input terminal of clock signal CLK of flip-flops FF1, FF2, FF3, and FF4 through a contact structure such as another via.

Shield lines 230, 231, 232a, 232b, 233a, 233b, 233c, 233d, 234a, 234b, 234c, 234d, 234e, 234f, 234g, and 234h provide shielding for corresponding clock lines formed at the same metal layer. In this embodiment, shield lines are electrically isolated from corresponding shield lines 210, 211, 212a, 212b, 213a, 213b, 213c, 213d, 214a, 214b, 214c, 214d, 214e, 214f, 214g, and 214h constituting a shield tree formed at the same metal layer.

Respective shield lines not constituting a shield tree can be grounded or can receive a specific voltage (e.g., power supply voltage Vdd). Consequently, the respective shield lines not constituting a shield tree are always set to have a constant voltage level and to provide shielding for the clock tree. That is, the shield lines not constituting a shield tree can be always maintained at a predetermined voltage level irrespective of the level of scan enable signal SE.

In semiconductor device 200, shield lines for transferring scan enable signal SE are electrically isolated from shield lines not constituting a shield tree. The respective shield lines, irrespective of whether they constitute a shield tree, are formed at the same layer to provide shielding to a clock line. Thus, semiconductor device 200 can efficiently use a metal source to form a shield tree.

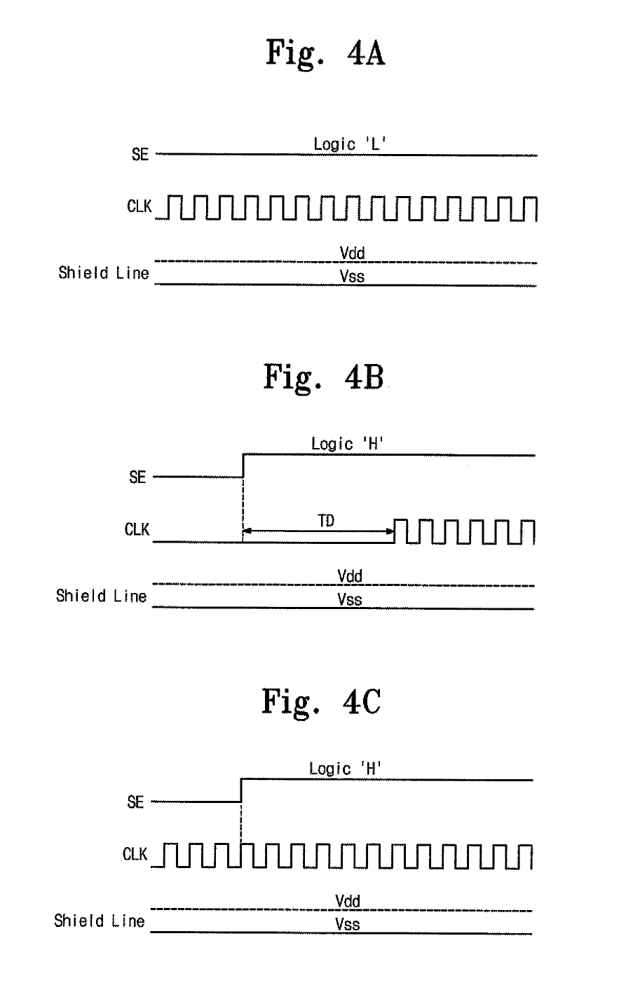

FIGS. 4A, 4B, and 4C are waveform timing diagrams illustrating voltage levels of a clock signal CLK, scan enable signal SE, and shield trees according to an embodiment of the inventive concept. FIG. 4A illustrates voltage levels of scan enable signal SE, clock signal CLK, and the shield lines in a normal operation mode, and FIG. 4B and 4C illustrate voltage levels of scan enable signal SE, clock signal CLK, and the shield lines in test operation modes.

Referring to FIG. 4A, scan enable signal SE is maintained at an inactive state (e.g., logic ‘low’) in the normal operation mode. Thus, shield lines 210, 211, 212a, 212b, 213a, 213b, 213c, 213d, 214a, 214b, 214c, 214d, 214e, 214f, and 214g, 214h constituting a shield tree electrically connected to an SE port are maintained at logic ‘low’ (e.g., ground VSS). As a result, the shield lines shield a clock line in the normal operation mode.

In the normal operation mode, shield lines 230, 231, 232a, 232b, 233a, 233b, 233c, 233d, 234a, 234b, 234c, 234d, 234e, 234f, 234g, and 234h not constituting a shield tree are fixed to a power supply voltage Vdd or ground Vss. As a result, shield lines not constituting a shield tree shield a clock line from interference caused by electromagnetic induction or coupling.

In FIG. 4B, voltage levels of scan enable signal SE, clock signal CLK, and the shield lines in the test operation mode are illustrated. To enter the test operation mode, scan enable signal SE is first activated (e.g., switched to logic ‘high’). After a lapse of specific delay time TD, clock signal CLK is input to a clock port and transmitted to flip-flops FF1˜FF16. In the test operation mode, specific delay time TD elapses between a point when scan enable signal SE is activated and a point when clock signal CLK is input. As a result, clock signal CLK provided to a clock line is substantially free from interference caused by transition of scan enable signal SE.

Also in the test operation mode, shield lines 230, 231, 232a, 232b, 233a, 233b, 233c, 233d, 234a, 234b, 234c, 234d, 234e, 234f, 234g, and 234h, which are electrically isolated from the shield lines not constituting a shield tree, receive power supply voltage Vdd or ground Vss. As a result, also in the test operation mode, the shield lines not constituting a shield tree may shield a clock tree from the interference caused by electromagnetic induction or coupling.

FIG. 4C illustrates waveforms of scan enable signal SE and clock signal CLK in another test operation mode. Scan enable signal SE is activated after clock signal CLK is provided. At a point when scan enable signal SE is deactivated (e.g., switched to logic ‘low’), shield lines constituting a shield tree may provide shielding to the clock tree and voltage levels of shield lines not constituting a shield tree are fixed to power supply voltage Vdd or ground Vss to provide shielding to the clock tree.

In this a manner, the shield lines provide shielding to the clock tree even at a point where scan enable signal SE is activated (e.g., switched to logic ‘high’). Interference is transferred to the clock tree at a point where scan enable signal SE transitions from logic ‘low’ to logic ‘high’. However, the transition of scan enable signal SE occurs for a very short time. Thus, the clock tree is effectively shielded through a shield tree structure of semiconductor device 200 described with reference to FIG. 3.

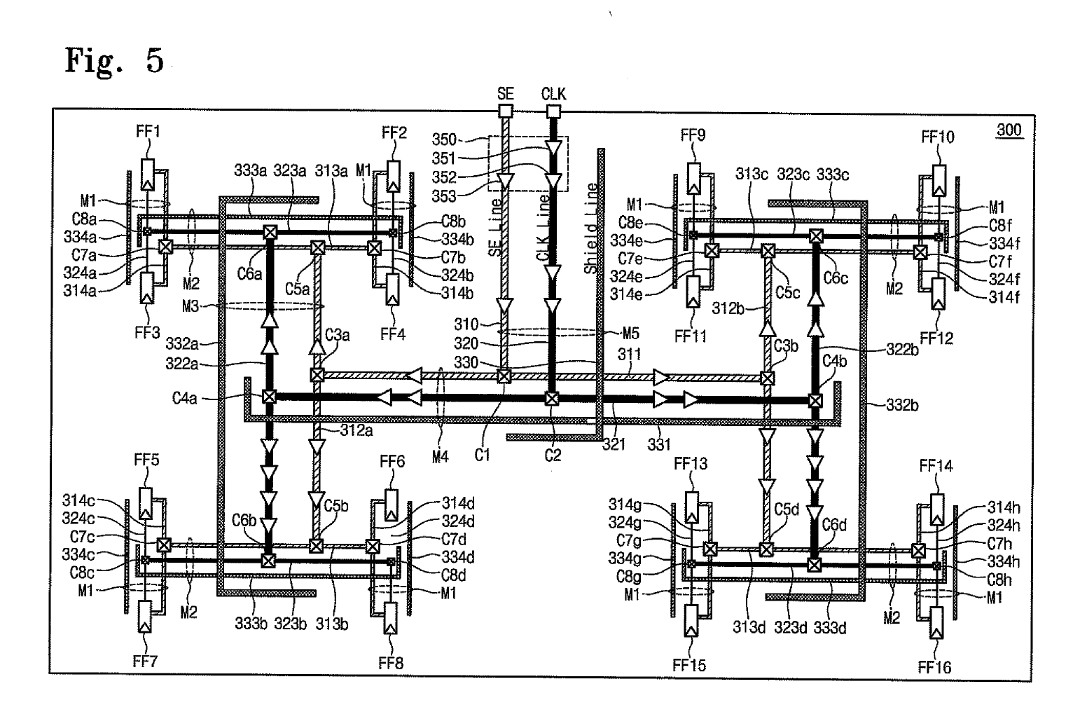

FIG. 5 is a block diagram of a semiconductor device 300 comprising a shield tree according to another embodiment of the inventive concept.

Referring to FIG. 5, semiconductor device 300 comprises a plurality of flip-flops FF1˜FF16 each receiving a clock signal CLK and a scan enable signal SE and clock lines 320, 321, 322a, 322b, 323a, 323b, 323c, 323d, 324a, 324b, 324c, 324d, 324e, 324f, 324g, and 324h constituting a shield tree transmitting a scan enable signal SE to flip-flops FF1˜FF16.

Semiconductor device 300 further comprises shield lines 330, 331, 332a, 332b, 333a, 333b, 333c, 333d, 334a, 334b, 334c, 334d, 334e, 334f, 334g, and 334h for shielding a clock tree. Shield lines constituting a shield tree and shield lines not constituting a shield tree are electrically isolated from each other.

Moreover, a buffer (or inverter) is included at a specific location of a clock tree and a shield tree.

Flip-flops FF1˜FF16 are circuits that store data input to semiconductor device 100 or internally processed data. Each of flip-flops FF1˜FF16 latches or outputs data in synchronization with a clock signal CLK transmitted through the clock tree. In a test mode, flip-flops FF1˜FF16 may store and output test data in response to a scan enable signal SE. Thus, scan enable signal SE is deactivated (e.g., logic ‘low’) in a normal operation mode.

Shield lines 310, 311, 312a, 312b, 313a, 313b, 313c, 313d, 314a, 314b, 314c, 314d, 314e, 314f, 314g, and 314h constituting a shield tree transmit a scan enable signal SE to flip-flops FF1˜FF16. Shield line 310 is formed at an uppermost meal layer (e.g., M5). Shield line 310 is electrically connected to an SE port to which a scan enable signal SE is externally input. Shield line 310 is electrically connected to shield line 311 formed at another metal layer M4 through a via C1.

Shield line 311 is electrically connected to shield lines 312a and 312b formed at another metal layer M3 through vias C3a and C3b. Shield line 312a is electrically connected to shield lines 313a and 313b formed at another metal layer M2 through vias C5a and C5b. Shield line 313a is electrically connected to shield lines 314a and 314b formed at another metal layer through vias C7a and C7b. Although not shown in the figures, shield lines 314a M1 and 314b may be electrically connected to an input terminal of scan enable signal SE of the respective flip-flops FF1, FF2, FF3, and FF4 through a contact structure such as another via.

Each of shield lines 310, 311, 312a, 312b, 313a, 313b, 313c, 313d, 314a, 314b, 314c, 314d, 314e, 314f, 314g, and 314h constituting a shield tree provides shielding to a clock tree while transmitting scan enable signal SE. That is, as scan enable signal SE is fixed to a logic ‘low’ in a normal operation mode, a shield tree blocks interference caused by electromagnetic induction or coupling transferred to the clock tree. As scan enable signal SE transitions to a logic ‘high’ in a test operation mode, a shield tree may block interference transferred to a clock tree.

Although only the shield lines connected to flip-flops FF1, FF2, FF3, and FF4 have been described herein, a method of forming a shield tree corresponding to flip-flops FF1˜FF4 may be similarly applied to shield lines transferred to flip-flops FF5˜FF16. Therefore, a connection relation of the shield tree with respect to the flips-flops FF5˜FF16 will not be described herein.

Clock lines 320, 321, 322a, 322b, 323a, 323b, 323c, 323d, 324a, 324b, 324c, 324d, 324e, 324f, 324g, and 324h constituting a clock tree transfer clock signal CLK to flip-flops FF1˜FF16. For brevity of description, only paths along which a clock signal is transmitted to flip-flops FF1˜FF4 will be described herein. However, a clock signal may be transmitted to flip-flops FF5˜FF16 in the same manner as in the case of flip-flops FF1˜FF4.

Clock line 320 may be formed at an uppermost metal layer (e.g., M5) among metal layers. Clock line 320 is electrically connected to a CLK port to which clock signal CLK is externally input. Clock line 320 is electrically connected to clock line 321 formed at another metal layer M4 through a via C2. The clock line and the shield lines are electrically isolated from each other.

Clock line 321 is electrically connected to clock lines 322a and 322b formed at another metal layer M3 through vias C4a and C4b. Clock line 322a is electrically connected to clock lines 323a and 323b formed at another metal layer M2 through vias C6a and C6b. Clock line 323a is electrically connected to clock lines 324a and 324b formed at another metal layer M1 through vias C8a and C8b. Although not shown in the figures, clock lines 324a and 324b may be electrically connected to an input terminal of clock signal CLK of flip-flops FF1, FF2, FF3, and FF4 through a contact structure such as another via.

Shield lines 330, 331, 332a, 332b, 333a, 333b, 333c, 333d, 334a, 334b, 334c, 334d, 334e, 334f, 334g, and 334h not constituting a shield tree provide shielding for corresponding clock lines formed at the same metal layers. In this embodiment, shield lines 330, 331, 332a, 332b, 333a, 333b, 333c, 333d, 334a, 334b, 334c, 334d, 334e, 334f, 334g, and 334h are electrically isolated from respective shield lines 310, 311, 312a, 312b, 313a, 313b, 313c, 313d, 314a, 314b, 314c, 314d, 314e, 314f, 314g, 314h constituting a shield tree at the same metal layer. Each of shield lines 330, 331, 332a, 332b, 333a, 333b, 333c, 333d, 334a, 334b, 334c, 334d, 334e, 334f, 334g, and 334h not constituting a shield tree may be grounded or may receive a specific voltage (e.g., power supply voltage Vdd). Thus, each of shield lines 330, 331, 332a, 332b, 333a, 333b, 333c, 333d, 334a, 334b, 334c, 334d, 334e, 334f, 334g, and 334h is always set to have a voltage of constant level and provide shielding for a clock tree. That is, shield lines 330, 331, 332a, 332b, 333a, 333b, 333c, 333d, 334a, 334b, 334c, 334d, 334e, 334f, 334g, and 334h may be always maintained at a predetermined voltage level, irrespective of the level of scan enable signal SE.

Particularly in the embodiment illustrated in FIG. 5, a buffer (or inverter) is included in a clock tree. In a region corresponding to a reference numeral 350 indicating a portion of semiconductor device 300, shield line 310, clock line 320, shield line 330 not constituting a shield tree, and buffers 351, 352, and 353 are shown. Specifically, clock buffers 351 and 352 formed at clock line 320 and a control buffer 353 formed at shield line 310 are shown. A design considering fan-out and delay for clock signal CLK is required to transfer clock signal CLK to a target element. In this case, a clock buffer (or inverter) is additionally provided onto a clock line to attenuate a clock signal or adjust delay of the clock signal. However, because a circuit such as a buffer (or inverter) is formed on a semiconductor substrate, a clock line formed at a metal layer may be connected to the buffer (or buffer) formed on the semiconductor substrate through a contact structure such as a via.

The shield effect of a shield line formed at the same metal layer as a clock line may be limited to a plane. Therefore, a clock line at a metal layer and a clock buffer (or inverter) on a substrate are connected through a contact structure such as a via to inset the clock buffer (or inverter). Because a via is formed to be perpendicular to a plane where a metal layer is formed, it is difficult to provide effective shielding for a via, connecting a clock line and a clock buffer to each other, through a shield line.

Semiconductor device 300 comprises a shield tree having the same contact structure as that formed at a clock line to inverter a clock buffer (or inverter). Although the embodiment illustrated in FIG. 5 has been described with respect to the construction where a buffer and a contact structure are inserted only into a shield line constituting a shield tree, it will be understood that a buffer circuit may be inserted into a shield line not constituting a shield tree in the same manner.

Additionally, a ratio of the number of clock buffers (or inverters) inserted into a clock tree to the number of control buffers inserted into a shield tree may be variously altered according to purposes. An additional process for forming a contact structure and security of a chip area for forming a buffer incur rising cost. Hence, the number of the control buffers inserted into a shield tree may be determined considering trade-off between the cost and the shield effect.

The ratio of buffers (or inverters) inserted into a clock tree and the number of buffers inserted into a shield tree may be set to 1 to 1 to maximize the shield effect. Alternatively, the ratio of buffers (or inverters) inserted into a clock tree and the number of buffers inserted into a shield tree may be set to n to 1 (n being an integer greater than 2) considering the cost. FIG. 5 shows a semiconductor device having a structure in which a ratio of the number of buffers inserted into a clock tree to the number of buffers into a shield tree is 2 to 1.

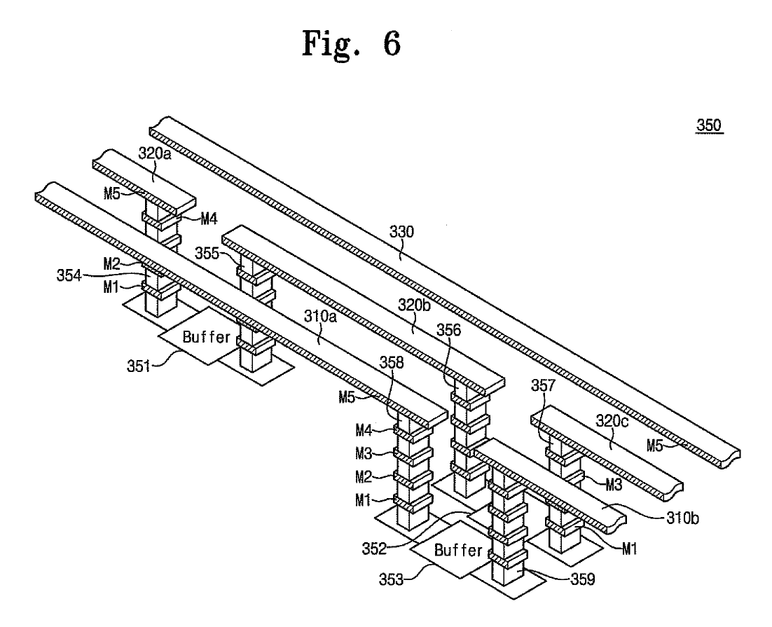

FIG. 6 is a cross-sectional view illustrating a detailed configuration of the region labeled with reference numeral 350 in FIG. 5.

Referring to FIG. 6, semiconductor device 300 comprises five metal layers M1˜M5 and a via for inserting a buffer is formed at both a shield tree and a clock tree. As discussed above, a via for inserting a buffer may also be formed at a shield line 330. In addition, a ratio of the number of buffers (or inverters) inserted into a clock tree to the number of buffers inserted into a shield tree is 2 to 1.

Clock lines 320a, 320b, and 320c are isolated from one another to be connected to two clock buffers 351 and 352 formed on a semiconductor substrate. Knot portions of isolated clock lines 320a, 320b, and 320c are connected to corresponding vias 354, 355, 356, and 357 formed in a vertical direction. A buffer 351 formed on the substrate and a clock line 320a formed at a metal layer M5 are electrically connected to each other by via 354. Clock buffer 351 formed on the substrate and clock line 320b formed at a metal layer M5 are electrically connected to each other by via 355. Clock buffer 352 formed on the substrate and clock line 320b formed at the metal layer M5 are electrically connected to each other by via 356. Clock buffer 352 formed on the substrate and clock line 320c formed at a metal layer M5 are electrically connected to each other by via 357.

Shield lines 310a and 310b are isolated from each other at metal layer M5 to be connected to control buffer 353 formed on the substrate. Knot portions of isolated shield lines 310a and 310b are connected to corresponding vias 358 and 359 formed in a vertical direction. Control buffer 353 formed on the substrate and shield line 310a formed at the metal layer M5 are electrically connected to each other by via 358. Control buffer 353 formed on the substrate and shield line 310b formed at the metal layer M5 are electrically connected to each other by via 359.

Shield line 330 is formed in parallel with clock lines 320a, 320b, and 320c. Although it is shown herein that a buffer (or inverter) and vias for connection to the buffer are not formed, a buffer for providing shielding in a vertical direction and vias can be formed at shield line 330.

Where vias 358 and 359 formed at shield lines 310a and 310b are omitted, shielding for vias 356 and 357 formed at clock lines 320b and 320c may not be provided. However, shielding for not only a metal layer but also vias 356 and 357 in a vertical direction can be provided by vias 358 and 359 formed at shield lines 310a and 310b. A fan-out phenomenon of clock signal CLK or scan control signal SE transferred to a clock line or a shield line through buffers 351, 352, and 353 can be prevented.

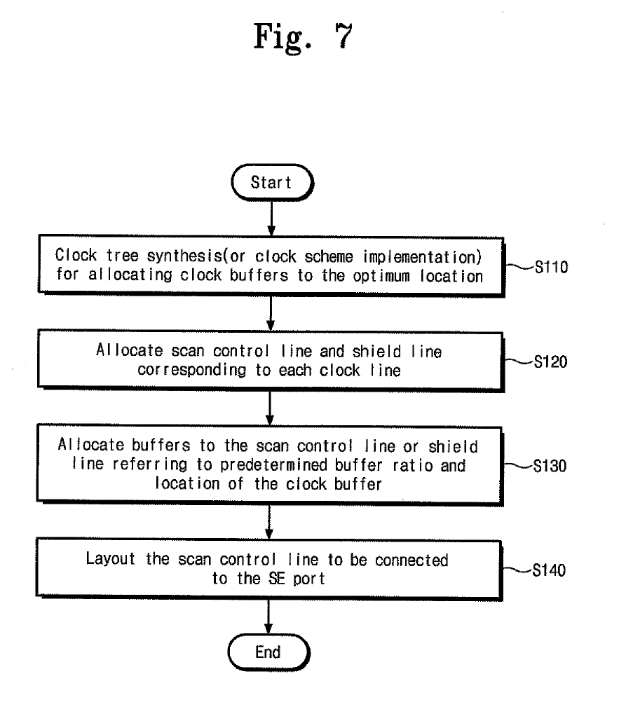

FIG. 7 is a flowchart illustrating a method of determining a layout for a shield tree and a clock tree according to an embodiment of the inventive concept. The method of FIG. 7 can be performed, for instance, by an electronic data processing apparatus such as a computer. In addition, the method can be performed in conjunction with the manufacture of a semiconductor device.

Referring to FIG. 7, in a step S110, a clock tree synthesis (CTS) or a clock scheme implementation in a layout step is carried out. In step S110, a clock tree or a clock line are formed in consideration of characteristics of a semiconductor device. In addition, clock buffers are allocated to locations in consideration of fan-out or clock skew.

In a step S120, locations of shield lines and a shield tree adjacent to a clock tree are determined. A shield tree and shield lines formed in the same metal layer are allocated to clock trees formed at respective metal layers. A shield tree is electrically connected shield lines in the embodiment of FIG. 1, whereas a shield tree and shield lines are routed to be electrically isolated from each other in the embodiment of FIGS. 3 and 4.

In a step S130, the number of buffers disposed on a shield tree and locations of the buffers are determined. The number of buffers inserted into the shield tree has a predetermined ratio with the number of clock buffers.

In a step S140, a shield tree is laid out to be electrically connected to scan enable signal SE. For example, shield lines (e.g., 110, 210 or 310) constituting a shield tree formed at an uppermost metal layer can form a layout to be connected to an input port of scan enable signal SE. Alternatively, a shield tree can be connected to an input port of a specific signal deactivated in a normal operation mode of a semiconductor device.

In some embodiments, the method of FIG. 7 can achieve effective interference blocking for a clock tree in a semiconductor device. While scan enable signal SE has been explained as one example of a control signal, other control signals can be used in various modes of the semiconductor device. For example, control signals can be used in test recovery modes of the semiconductor device, such as built-in self-test (BIST) or built-in redundancy analysis (BIRA).

Semiconductor devices according to various embodiments of the inventive concept can be incorporated in various types of packages or package configurations. For example, a flash memory device and/or a memory controller can be packaged in package types such as package (PoP), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flatpack (TQFP), small outline integrated circuit (SOIC), shrink small outline package (SSOP), thin small outline package (TSOP), system in package (SIP), multi chip package (MCP), wafer-level fabricated package (WFP), and wafer-level processed stack package (WSP).

As indicated by the foregoing, in certain embodiments of the inventive concept, a semiconductor device comprising a shield tree can provide improved reliability of a clock signal and can reduce the amount of metal used to form the shield tree.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims.

What is claimed is:

1. A semiconductor device comprising:
a plurality of flip-flops;
a clock tree for transferring an externally generated input clock signal to the plurality of flip-flops; and
a shield tree formed to provide shielding to the clock tree,
wherein the shield tree transmits a control signal to activate the flip-flops in a test operation mode of the semiconductor device.

2. The semiconductor device of claim 1, wherein the clock tree comprises a plurality of metal clock lines formed in a plurality of metal layers and connected to each other through corresponding vias.

3. The semiconductor device of claim 1, wherein the shield tree comprises a first shield tree that transmits the control signal and a second shield tree electrically isolated from the first shield tree.

4. The semiconductor device of claim 3, wherein the first shield tree comprises a plurality of metal shield lines formed in a plurality of metal layers and connected to each other through corresponding vias.

5. The semiconductor device of claim 4, wherein the second shield tree is connected to a power supply voltage or ground.

6. The semiconductor device of claim 1, further comprising a plurality of clock buffers connected to the clock tree to control fan-out and skew of the clock signal.

7. The semiconductor device of claim 6, further comprising a plurality of control signal buffers formed in the shield tree adjacent to the clock buffers and configured to transmit the control signal.

8. The semiconductor device of claim 7, wherein each of the clock buffers and control signal buffers comprises an inverter circuit.

9. The semiconductor device of claim 7, wherein the control signal buffers provide shielding to a via through which the clock buffers are connected to the clock tree.

10. The semiconductor device of claim 1, further comprising:
a clock signal input port that receives the clock signal from an external source and transmits the clock signal to the clock tree; and
a control signal input port that receives the control signal from an external source and transmits the control signal to the shield tree.

11. The semiconductor device of claim 10, wherein the control signal is deactivated during a normal operation mode of the semiconductor device.

12. The semiconductor device of claim 10, wherein the clock signal input port transmits the clock signal to the clock tree after a lapse of specific delay time from a transition point of the control signal in the test operation mode of the semiconductor device.

13. A computer-implemented method of determining a layout for a semiconductor device comprising a plurality of flip-flops, the method comprising:
determining a layout of a clock tree for transmitting a clock signal to the respective flip-flops; and
determining a layout of a shield tree for shielding the clock tree,
wherein the shield tree is configured to transmit a control signal for activating a test operation mode of the flip-flops, and the shield tree is configured to be connected to an input port of the control signal.

14. The method of claim 13, wherein the shield tree comprises a first shield tree configured to transmit the control signal and a second shield tree electrically isolated from the first shield tree.

15. The method of claim 14, wherein the second shield tree is configured to be connected to a power supply voltage or ground.

16. The method of claim 14, wherein determining the layout of the clock tree comprises allocating a plurality of clock buffers to the clock tree to control fan-out and delay of the clock signal.

17. The method of claim 16, wherein determining the layout of the shield tree comprises allocating a plurality of control signal buffers to the shield tree to transmit the control signal, and the control signal buffers are formed adjacent to the clock buffers.

18. A method of performing a test operation in a semiconductor device comprising a plurality of flip-flops, a clock tree for transferring an externally generated input clock signal to the plurality of flip-flops, and a shield tree formed to provide shielding to the clock tree, the method comprising:
transmitting a control signal through the shield tree to activate the flip-flops in a test operation mode of the semiconductor device.

19. The method of claim 18, further comprising:
deactivating the control signal during a normal operation mode of the semiconductor device.

20. The method of claim 18, wherein the semiconductor device comprises a flash memory device.
